(19) United States
(12) Patent Application Publication
(10) Pub. No.: US 2024/0116044 A1
(43) Pub. Date: Apr. 11, 2024

(54) MANUFACTURING METHOD OF PLATINUM-BASED ALLOY CATALYST USING FLUIDIZED ATOMIC LAYER DEPOSITION

(71) Applicants: HYUNDAI MOTOR COMPANY, Seoul (KR); KIA CORPORATION, Seoul (KR); Institute for Research & Industry Cooperation Pusan National University, Busan (KR)

(72) Inventors: Jung Yeon Park, Hwaseong-si (KR); Woong Pyo Hong, Suwon-si (KR); Seung Jeong Oh, Hwaseong-si (KR); Se Hun Kwon, Busan (KR); Susanta Bera, Busan (KR); Hyun Jae Woo, Busan (KR); Woo Jae Lee, Busan (KR)

(21) Appl. No.: 18/136,468

(22) Filed: Apr. 19, 2023

(30) Foreign Application Priority Data
Oct. 5, 2022 (KR) 10-2022-0126863

(51) Int. Cl. B01J 37/02; B01J 19/18; B01J 23/89; B01J 37/08; C23C 16/18; C23C 16/455

(52) U.S. Cl. CPC B01J 37/0215; B01J 19/18; B01J 23/892; B01J 37/08; C23C 16/18; C23C 16/45527; C23C 16/45544

(57) ABSTRACT

An atomic layer deposition method for manufacturing a platinum-based alloy catalyst includes applying a support in a reactor and depositing an alloy of platinum and a non-platinum metal on the support through a super cycle comprising a first sub-cycle and a second sub-cycle.

### CROSS REFERENCE TO RELATED APPLICATIONS

The present application claims priority to Korean Patent Application No. 10-2022-0126863, filed Oct. 5, 2022, the entire contents of which is incorporated herein for all purposes by this reference.

### BACKGROUND

### 1. Field

The present disclosure relates to a method for manufacturing a platinum-based alloy catalyst by atomic layer deposition.

### 2. Description of the Related Art

Fuel depletion, rising temperature, and fine dust caused by the indiscriminate use of fossil fuels are becoming problems worldwide. Accordingly, research on renewable energy to replace fossil fuels is being conducted as a hot issue. As a part of this, research on fuel cells that produce electrical energy through a chemical reaction between hydrogen and oxygen has been actively conducted for decades. In particular, the polymer electrolyte exchange membrane fuel cell has advantages such as high efficiency, fast start-up, and high output voltage, and thus can be applied to transportation and power generation fields.

However, in the polymer electrolyte exchange membrane fuel cell, the oxygen generation reaction of an anode is very slow, so a platinum catalyst with high activity must be used to compensate for this. The high price of platinum catalysts and the decrease in durability due to degradation under actual operating conditions are the main causes of slowing the commercialization of polymer electrolyte exchange membrane fuel cells.

In order to reduce the amount of platinum, efforts are being made to reduce the amount of platinum particles by controlling the size and distribution of platinum particles, manufacturing platinum-based alloy catalysts, and manufacturing non-platinum metal catalysts.

Since research on controlling the particle size and distribution of platinum has already been conducted considerably, it is unlikely that a new innovative method will be developed. In addition, it seems that further studies are needed to reach the activity of the non-platinum metal catalyst to reach the activity of the platinum catalyst. Therefore, a platinum-based alloy catalyst is considered an ideal catalyst.

It is reported that an alloy catalyst is more active in oxygen generation reactions due to surface atom distribution, electron structure change by metal-metal interaction, and catalyst activity change by lattice constant mismatch, and is more durable than the existing platinum catalyst.

### SUMMARY

An objective of the present disclosure is to provide a method for manufacturing an alloy catalyst that can easily control the composition of the alloy, exhibit high uniformity, and can accurately control the size of the alloy.

Another objective of the present disclosure is to provide a method for manufacturing an alloy catalyst capable of simplifying the production process and reducing the manufacturing cost.

The other objective of the present disclosure is to provide a method for manufacturing an alloy catalyst having high activity and excellent durability.

The objective of the present disclosure is not limited to the objective mentioned above. The objectives of the present disclosure will become more apparent from the following description and will be realized by means and combinations thereof described in the claims.

The method for manufacturing an alloy catalyst, according to an embodiment of the present disclosure, may include applying a support in a reactor; and depositing an alloy of platinum and a non-platinum metal on the support through a super cycle including a first sub-cycle and a second sub-cycle.

The first sub-cycle may include injecting a platinum precursor into the reactor so that the platinum precursor is adsorbed onto the support, injecting a first purge gas into the reactor, depositing platinum on the support by injecting a reaction gas into the reactor, and injecting a second purge gas into the reactor.

The second sub-cycle may include injecting a non-platinum metal precursor into the reactor so that the non-platinum metal precursor is adsorbed onto the support, injecting a third purge gas into the reactor, depositing non-platinum metal on the support by injecting a reaction gas into the reactor, and injecting a fourth purge gas into the reactor.

The reactor may include a fluidized bed reactor or a rotary reactor.

The support may include at least one selected from the group consisting of a carbon-based support, a metal oxide-based support, and a combination thereof.

The platinum precursor may include at least one selected from the group consisting of trimethyl(methylcyclopentadienyl) platinum(IV) (MeCpPtMe₃), platinum(II) bis(acetylacetonate) (Pt(acac)₂), [(1,2,5,6-η)-1,5-hexadiene]dimethyl platinum(II) (HDMP), dimethyl(N,N-dimethyl-3-butene-1-amine-N) platinum (DDAP), and a combination thereof.

The reaction gas may include at least one selected from the group consisting of oxygen (O₂), ozone (O₃), air, hydrogen (H₂), oxygen plasma (O₂ plasma), and a combination thereof.

The depositing the platinum on the support may be performed by a powder atomic layer deposition method.

The first purge gas, the second purge gas, the third purge gas and the fourth purge gas may each include at least one selected from the group consisting of argon (Ar), helium (He), nitrogen (N₂), and a combination thereof.

The non-platinum metal may include at least one selected from the group consisting of palladium (Pd), gold (Au), silver (Ag), copper (Cu), iron (Fe), cobalt (Co), nickel (Ni), molybdenum (Mo), ruthenium (Ru), rhodium (Rh), tungsten (W), iridium (Ir), and a combination thereof.

The depositing the non-platinum metal on the support may be performed by a powder atomic layer deposition method.

During the super cycle, gas may be continuously injected into the fluidized bed reactor to maintain the support in a fluidized state.

The super cycle may include performing the first sub-cycle 2 to 10 times and then performing the second sub-cycle 1 to 3 times.

The super cycle may include performing the second sub-cycle 1 to 3 times and then performing the first sub-cycle 2 to 10 times.

The super cycle may be repeated 1 to 10 times.

The super cycle may be performed in a temperature of 100° C. to 400° C.

The manufacturing method may further include heat treating a resultant of the super cycle.

The resultant may be heat-treated in a gas atmosphere including at least one selected from the group consisting of hydrogen (H₂), ammonia (NH₃), nitrogen (N₂), argon (Ar), and a combination thereof.

The resultant may be heat-treated in a temperature of 400° C. to 1,100° C.

The alloy catalyst may include 75 at % to 85 at % of the platinum and 15 at % to 25 at % of the non-platinum metal.

According to the present disclosure, it is possible to obtain a method for manufacturing an alloy catalyst that may easily control the composition of the alloy, show high uniformity, and accurately control the catalyst size.

According to the present disclosure, it is possible to obtain a method for manufacturing an alloy catalyst capable of simplifying the manufacturing process and reducing the manufacturing cost.

According to the present disclosure, an alloy catalyst having high activity and excellent durability may be manufactured.

The effects of the present disclosure are not limited to the effects mentioned above. It should be understood that the effects of the present disclosure include all effects that can be inferred from the following description.

### BRIEF DESCRIPTION OF THE FIGURES

FIG. 1 shows a super cycle according to the present disclosure;

FIG. 2 shows the deposition rate of the platinum thin film according to the injection time of the platinum precursor;

FIG. 3 shows the deposition rate of the nickel thin film according to the injection time of the nickel precursor;

FIG. 4 shows the thickness according to the atomic layer deposition cycle;

FIG. 5 shows a result of X-ray diffraction analysis of alloy catalysts according to Examples 1 to 4 and Comparative Examples;

FIG. 6A shows the particle size and distribution of the alloy catalyst according to Example 1;

FIG. 6B shows the particle size and distribution of the alloy catalyst according to Example 2;

FIG. 6C shows the particle size and distribution of the alloy catalyst according to Example 3;

FIG. 6D shows the particle size and distribution of the alloy catalyst according to Example 4;

FIG. 6E shows the particle size and distribution of the alloy catalyst according to a Comparative Example;

FIG. 7A shows a result of analyzing the alloy catalyst according to Example 1 with a high-resolution transmission electron microscope;

FIG. 7B shows a result of analyzing the alloy catalyst according to Example 2 with a high-resolution transmission electron microscope;

FIG. 7C shows a result of analyzing the alloy catalyst according to Example 3 with a high-resolution transmission electron microscope;

FIG. 8A shows a result of line profiling to determine the composition distribution of one alloy catalyst particle in FIG. 7A;

FIG. 8B shows a result of line profiling to determine the composition distribution of one alloy catalyst particle in FIG. 7B;

FIG. 8C shows a result of line profiling to determine the composition distribution of one alloy catalyst particle in FIG. 7C;

FIG. 9 shows an electron energy loss spectroscopy result for the alloy catalyst according to Example 2;

FIG. 10 shows a result of a low-angle X-ray photoelectron spectroscopy (XPS) of the alloy catalyst according to Example 2 and Comparative Example;

FIG. 11 shows a result of analyzing the alloy catalysts according to Examples 1 to 4 by cyclic voltammetry;

FIG. 12 shows a result of measuring the electrochemically active surface area of each alloy catalyst through the results of FIG. 11;

FIG. 13 shows a result of measuring the activity for oxygen reduction reaction by analyzing the alloy catalysts according to Examples 1 to 4 by a linear scanning potential method;

FIG. 14 shows the activity per platinum mass and the activity per platinum surface area based on the results of FIG. 13;

FIG. 15 shows a polarization curve of a polymer electrolyte exchange membrane fuel cell to which an alloy catalyst, according to Examples 1 to 3, is applied;

FIG. 16 shows a power density curve of a polymer electrolyte exchange membrane fuel cell to which an alloy catalyst, according to Examples 1 to 3, is applied;

FIG. 17 shows the activity per mass of an alloy catalyst in a fuel cell to which the alloy catalyst, according to Examples 1 to 3, is applied;

FIG. 18 shows a result of measuring the active surface area of the alloy catalyst when the polymer electrolyte exchange membrane fuel cell to which the alloy catalyst, according to Example 2, is applied is operated by the degradation cyclic voltammetry; and

FIG. 19 shows a result of measuring the activity per platinum mass of the alloy catalyst when the polymer electrolyte exchange membrane fuel cell to which the alloy catalyst, according to Example 2, is applied is operated by the degradation linear scanning potential method.

### DETAILED DESCRIPTION

The above objectives, other objectives, features, and advantages of the present disclosure will be easily understood through the following preferred embodiments in conjunction with the accompanying drawings. However, the present disclosure is not limited to the embodiments described herein and may be embodied in other forms. Rather, the embodiments introduced herein are provided so that the disclosed content may be thorough and complete, and the spirit of the present disclosure may be sufficiently conveyed to those skilled in the art.

Like reference numerals have been used for like elements in describing each figure. In the accompanying drawings, the dimensions of the structures are enlarged more than the actual size for clarity of the present disclosure. Terms such as first, second, etc., may be used to describe various elements, but the elements should not be limited by the terms. The above terms are used only for the purpose of distinguishing one component from another. For example, without departing from the scope of the present disclosure, a first component may be referred to as a second component, and similarly, a second component may also be referred to as a first component. The singular expression includes the plural expression unless the context clearly dictates otherwise.

In this specification, the terms “include” or “have” should be understood to designate that one or more of the described features, numbers, steps, operations, components, or a combination thereof exist, and the possibility of addition of one or more other features or numbers, operations, components, or combinations thereof should not be excluded in advance. Also, when a part of a layer, film, region, plate, etc., is said to be “on” another part, this includes not only the case where it is “on” another part but also the case where another part is in the middle. Conversely, when a part of a layer, film, region, plate, etc., is said to be “under” another part, this includes not only cases where it is “directly under” another part but also a case where another part is in the middle.

Unless otherwise specified, all numbers, values, and/or expressions expressing quantities of ingredients, reaction conditions, polymer compositions, and formulations used herein contain all numbers, values and/or expressions in which such numbers essentially occur in obtaining such values, among others. Since they are approximations reflecting various uncertainties in the measurement, they should be understood as being modified by the term “about” in all cases. In addition, when a numerical range is disclosed in this disclosure, this range is continuous and includes all values from the minimum to the maximum value containing the maximum value of this range unless otherwise indicated. Furthermore, when such a range refers to an integer, all integers, including the minimum value to the maximum value containing the maximum value, are included unless otherwise indicated.

The method for manufacturing an alloy catalyst, according to the present disclosure, may be to deposit an alloy of platinum and non-platinum metal on the support through a super cycle including a first sub-cycle and a second sub-cycle, in which the first sub-cycle using a platinum precursor and the second sub-cycle using a non-platinum metal precursor are introduced into the reactor.

First, the support may be introduced into the reactor.

The type of the reactor is not particularly limited and may include, for example, a fluidized bed reactor or a rotary reactor.

The type of the support is not particularly limited but may include a carbon-based support and/or a metal oxide-based support. For example, the carbon-based support may include at least one selected from the group consisting of carbon black, graphene, carbon nanotubes, and a combination thereof. The metal oxide-based support may include at least one selected from the group consisting of ZrO₂, MgO, TiO₂, Al₂O₃, SiO₂, CrO₂, Fe₂O₃, Fe₃O₄, CuO, ZnO, CaO, Sb₂O₄, CO₃O₄, Fe₃O₄, Pb₃O₄, Mn₃O₄, Ag₂O₂, U₃O₈, Cu₂O, Li₂O, Rb₂O, Ag₂O, Ti₂O, BeO, CdO, TiO, GeO₂, HfO₂, PbO₂, MnO₂, TeO₂, SnO₂, La₂O₃, Fe₂O₃, CeO₂, WO₂, UO₂, ThO₂, TeO₂, MoO₃, and a combination thereof.

After the support is introduced, the inside of the reactor may be made into a vacuum state to form a base pressure. The method is not particularly limited, and a vacuum state may be created using a vacuum pump connected to the reactor or the like.

The internal pressure of the reactor may be in a range of 0.1 Torr to 0.6 Torr. When the base pressure within the above numerical range is formed in the reactor, the support is fluidized and floated. Accordingly, the contact area and the number of contact between the platinum precursor, the non-platinum metal precursor, and the support increases, and platinum precursor and non-platinum metal precursor can be more effectively adsorbed and/or deposited on the support.

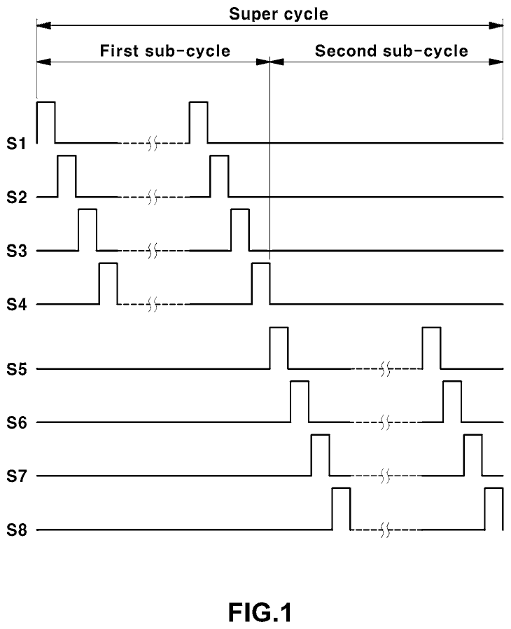

FIG. 1 shows a super cycle according to the present disclosure. Referring to FIG. 1, the super cycle may be provided to include a first sub-cycle and a second sub-cycle.

The first sub-cycle may include injecting a platinum precursor into the reactor so that the platinum precursor is adsorbed onto the support S1, injecting a first purge gas into the reactor S2, depositing platinum on the support by injecting a reaction gas into the reactor S3, and injecting a second purge gas into the reactor S4.

The second sub-cycle may include injecting a non-platinum metal precursor into the reactor so that the non-platinum metal precursor is adsorbed onto the support S5, injecting a third purge gas into the reactor S6, depositing non-platinum metal on the support by injecting a reaction gas into the reactor S7, and injecting a fourth purge gas into the reactor S8.

The platinum precursor may include at least one selected from the group consisting of trimethyl(methylcyclopentadienyl) platinum(IV) (MeCpPtMe₃), platinum(II) bis(acetylacetonate) (Pt(acac)₂), [(1,2,5,6-η)-1,5-hexadiene]dimethyl platinum(II) (HDMP), dimethyl(N,N-dimethyl-3-butene-1-amine-N) platinum (DDAP), and a combination thereof.

The platinum precursor may be injected into the reactor through a carrier gas S1. The carrier gas may include any material that does not react with the platinum precursor, and may include, for example, argon (Ar), helium (He), nitrogen (N₂), or the like.

The platinum precursor may be injected into the reactor for 90 seconds to 150 seconds at a flow rate of 50 sccm to 200 sccm. The flow rate and injection time of the platinum precursor may mean the flow rate and injection time of the carrier gas. When the flow rate and injection time of the platinum precursor fall within the above numerical ranges, the platinum precursor may be sufficiently adsorbed onto the support.

The temperature of the platinum precursor may be in a range of 20° C. to 50° C.

Thereafter, the first purge gas may be injected into the reactor to remove the platinum precursor not adsorbed to the support S2.

The first purge gas may include any material that does not react with the platinum precursor, and may include, for example, at least one selected from the group consisting of argon (Ar), helium (He), nitrogen (N₂), and a combination thereof.

The first purge gas may be injected into the reactor for 60 seconds to 120 seconds at a flow rate of 50 sccm to 200 sccm. When the flow rate and injection time of the first purge gas falls within the above numerical ranges, it is possible to effectively remove the non-adsorbed platinum precursor.

The depositing the platinum on the support S3 may be performed by a powder atomic layer deposition method. For example, platinum derived from the platinum precursor may be deposited on the support by injecting a reaction gas into the reactor and generating plasma or applying heat to remove the ligand of the platinum precursor.

The reaction gas may include at least one selected from the group consisting of oxygen (O₂), ozone (O₃), air, hydrogen (H₂), oxygen plasma (O₂ plasma), and a combination thereof. Preferably, the reaction gas may include oxygen (O₂).

The reaction gas may be injected into the reactor for 60 seconds to 120 seconds at a flow rate of 10 sccm to 200 sccm. When the flow rate and injection time of the reaction gas falls within the above numerical ranges, the ligand of the platinum precursor may be effectively removed to deposit platinum on the support.

Thereafter, the second purge gas may be injected into the reactor to remove residues therein S4.

The second purge gas may include at least one selected from the group consisting of argon (Ar), helium (He), nitrogen (N₂), and a combination thereof.

The second purge gas may be injected into the reactor for 60 seconds to 120 seconds at a flow rate of 50 sccm to 200 sccm. When the flow rate and injection time of the second purge gas falls within the above numerical ranges, it is possible to sufficiently remove the residue inside the reactor.

The first sub-cycle may be to repeat the above steps several times. This will be described later.

As shown in FIG. 1, after completing the first sub-cycle, the second sub-cycle may be performed immediately in some embodiments. On the other hand, a time interval may be provided between the first sub-cycle and the second sub-cycle, and in this case, it may be desirable to inject a purge gas into the reactor to maintain the flow state of the support.

The second sub-cycle may start with step S5 of injecting a non-platinum metal precursor into the reactor to adsorb the non-platinum metal precursor to a support.

The non-platinum metal may include at least one selected from the group consisting of palladium (Pd), gold (Au), silver (Ag), copper (Cu), iron (Fe), cobalt (Co), nickel (Ni), molybdenum (Mo), ruthenium (Ru), rhodium (Rh), tungsten (W), iridium (Ir), and a combination thereof.

The palladium (Pd) precursor may include at least one selected from the group consisting of palladium(II) hexafluoroacetyl acetonate (Pd(hfac)₂), palladium tetramethyl heptanedionate (Pd(thd)₂), palladium-ketoiminato (Pd(keim₂)₂), and a combination thereof.

The silver (Ag) precursor may include at least one selected from the group consisting of (2,2-dimethylpropionato)silver(I) triethylphosphine (Ag(O₂CtBu)(PEt₃)), (1,5-cyclooctadiene)(hexafluoroacetyl acetonato)silver(I) (Ag(hfac)(cod)) and a combination thereof.

The copper(Cu) precursor may include at least one selected from the group consisting of copper(I) chloride (CuCl), copper(II) hexafluoroacetyl acetonate hydrate (Cu(hfac)₂), copper(II) acetylacetonate (Cu(acac)₂), copper bis(2,2,6,6-tetra methyl-3,5-heptanedionate) (Cu(thd)₂), bis(dimethylamino-2-propoxy)copper(II) (Cu(dmap)₂), bis(N,N′-di-i-propylacetamidinato)copper(II) ([Cu(iPrNCMeNiPr)]₂), bis(N,N′-di-sec-butylacetamidinato)dicopper(I) ([Cu(sBuNCMeNsBu)]₂) and a combination thereof.

The iron (Fe) precursor may include bis(N,N′-di-sec-butylacetamidinato)iron(I) (Fe(iBuNCMeNtBu)₂).

The cobalt (Co) precursor may include at least one selected from the group consisting of bis(N,N′-di-i-propylacetamidinato)cobalt(II) (Co(iPrNCMeNiPr)₂), bis(cyclopentadienyl)cobalt(II) (CoCp₂), cyclopentadienylcobalt dicarbonyl (CoCp(CO)₂), cobalt carbonyl(dicobalt octacarbonyl) (Co₂(CO)₈), and a combination thereof.

The nickel (Ni) precursor may include at least one selected from the group consisting of bis(N,N′-di-i-propylacetamidinato)nickel(II) (Ni(iPrNCMeNiPr)₂), nickel(II) acetylacetonate (Ni(acac)₂), nickel heptafluoroisopropyl (Ni(hfip)₂), bis(1-dimethylamino-2-methyl-2-butoxide)nickel(II) (Ni(dmamb)₂), and a combination thereof.

The molybdenum (Mo) precursor may include molybdenum (V) chloride (MoCl₅).

The ruthenium(Ru) precursors may include at least one selected from the group consisting of bis(cyclopentadienyl)ruthenium (Ru(Cp)₂), bis(ethylcyclopentadienyl)ruthenium(II) (Ru(EtCp)₂), methylcyclopentadienyl ethylcyclopentadienyl ruthenium ((EtCp)Ru(MeCp)), (Me₃NEtCp)RuCp, cyclopentadienyl ethyl (dicarbonyl)ruthenium (Ru(Cp)(CO)₂Et), N,N-Dimethyl-1-ruthenocenylethylamine (RuCp(CpCh(Me)(NMe₂))), tris(2,2,6,6-tetramethyl-3,5-heptanedionate) ruthenium(III) (Ru(thd)₃), bis(N,N-di-t-butylacetamidinato)ruthenium(II) dicarbonyl (Ru(tBuAMD)₂(CO)₂, rudic, carish and a combination thereof.

The tungsten (W) precursor may include tungsten hexafluoride (WF₆).

The iridium (Ir) precursor may include at least one selected from the group consisting of iridium(III) acetylacetonate (Ir(acac)₃), iridium(ethylcyclopentadienyl)(1,5-cyclooctadiene) (Ir(EtCp)(cod)), 1-ethylcyclopentadienyl-1,3-cyclohexadieneiridium(I) (Ir(MeCp)(chd)), and a combination thereof.

The non-platinum metal precursor may be injected into the reactor through a carrier gas. The carrier gas may include any material that does not react with the non-platinum metal precursor and may include, for example, argon (Ar), helium (He), nitrogen (N₂), or the like.

The non-platinum metal precursor may be injected into the reactor for 200 seconds to 300 seconds at a flow rate of 50 sccm to 200 sccm. The flow rate and injection time of the non-platinum metal precursor may mean the flow rate and injection time of the carrier gas. When the flow rate and injection time of the non-platinum metal precursor fall within the above numerical ranges, the non-platinum metal precursor may be sufficiently adsorbed onto the support.

The temperature of the non-platinum metal precursor may be in a range of 50° C. to 90° C.

Thereafter, the third purge gas may be injected into the reactor to remove the non-platinum metal precursor not adsorbed to the support S6.

The third purge gas may include any material that does not react with the non-platinum metal precursor and may include, for example, at least one selected from the group consisting of argon (Ar), helium (He), nitrogen (N₂), and a combination thereof.

The third purge gas may be injected into the reactor for 60 seconds to 120 seconds at a flow rate of 50 sccm to 200 sccm. When the flow rate and injection time of the third purge gas falls within the above numerical ranges, it is possible to effectively remove the non-adsorbed non-platinum metal precursor.

The depositing the non-platinum metal on the support S7 may be performed by a powder atomic layer deposition method. For example, non-platinum metal derived from the non-platinum metal precursor may be deposited on the support by injecting a reaction gas into the reactor and generating plasma or applying heat to remove the ligand of the non-platinum metal precursor.

The reaction gas may include at least one selected from the group consisting of oxygen (O₂), ozone (O₃), air, hydrogen (H₂), oxygen plasma (O₂ plasma), and a combination thereof. Preferably, the reaction gas may include hydrogen (H₂).

The reaction gas may be injected into the reactor for 60 seconds to 120 seconds at a flow rate of 100 sccm to 300 sccm. When the flow rate and injection time of the reaction gas falls within the above numerical ranges, the ligand of the non-platinum metal precursor may be effectively removed to deposit non-platinum metal on the support.

Thereafter, the fourth purge gas may be injected into the reactor to remove residues therein S8.

The fourth purge gas may include at least one selected from the group consisting of argon (Ar), helium (He), nitrogen (N₂), and a combination thereof.

The fourth purge gas may be injected into the reactor for 60 seconds to 120 seconds at a flow rate of 50 sccm to 200 sccm. When the flow rate and injection time of the fourth purge gas falls within the above numerical ranges, it is possible to sufficiently remove the residue inside the reactor.

The second sub-cycle may be to repeat the above steps several times, which will be described later.

As shown in FIG. 1, it may be preferable to continuously inject the carrier gas, the purge gases, the reaction gas, and the like into the reactor while performing the super cycle to maintain the support in a fluidized state.

In the super cycle, the first sub-cycle may be performed 2 to 30 times and then the second sub-cycle may be performed 1 to 3 times. Also, in the super cycle, the second sub-cycle may be performed 1 to 3 times and then the first sub-cycle may be performed 2 to 30 times.

The present disclosure is characterized in that the super cycle configured as above is repeatedly performed 1 to 10 times. The number of sub-cycles and super-cycles may be appropriately adjusted in consideration of the composition of the alloy catalyst, particle size, process stability, and the like.

The super cycle may be performed in a temperature of 100° C. to 400° C. This temperature may be a temperature condition for depositing and alloying the platinum and non-platinum metal on the support.

The method of manufacturing an alloy catalyst, according to the present disclosure, may further include heat treating a resultant of the super cycle. Alloying occurs more easily by removing impurities such as oxygen through heat treatment, and a platinum layer, in which platinum is the main component, may be formed on the surface of the catalyst. Here, platinum as the main component means that platinum is contained in a series of layers from the surface to a certain depth at 50 at % or more, 60 at % or more, 70 at % or more, 80 at % or more, 90 at % or more, or 99 at % or more. The alloy catalyst of platinum and non-platinum metal has a problem in that durability and activity are degraded as a reaction between non-platinum metal alloyed and mainly transition metals proceeds when used for a long period of time. As in the present disclosure, when a platinum layer, which is the main component, is formed on the surface of the alloy catalyst, the above problem may be prevented.

The heat treatment may be performed in a gas atmosphere including at least one selected from the group consisting of hydrogen (H₂), ammonia (NH₃), nitrogen (N₂), argon (Ar), and a combination thereof.

In addition, the heat treatment may be performed at a temperature of 400° C. to 1,100° C.

The alloy catalyst prepared as described above may include 75 to 85 at % of the platinum and 15 to 25 at % of the non-platinum metal. The at % of the above metals is based on the total at % of the active metal excluding the support. When the content of the platinum and the non-platinum metal falls within the above numerical range, the activity and durability of the alloy catalyst can be improved in a balanced way.

Hereinafter, another form of the present disclosure will be described in more detail through the following examples. The following examples are merely illustrative to help the understanding of the present disclosure, and the scope of the present disclosure is not limited thereto.

### Reference Example

The present inventors tested whether platinum and non-platinum metal can be deposited by the fluidized-bed atomic layer deposition method.

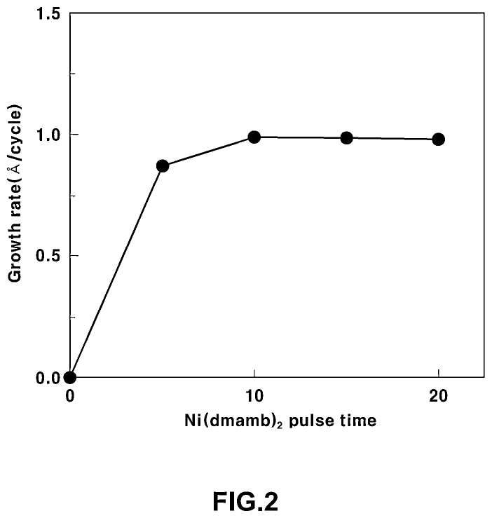

First, a SiO₂ substrate was put into a fluidized bed reactor, and a platinum precursor, trimethyl(methylcyclopentadienyl)platinum(IV) (MeCpPtMe₃), was injected using a carrier gas for a predetermined period of time. Specifically, the temperature of the platinum precursor was about 30° C., and the flow rate of the carrier gas was about 100 sccm. FIG. 2 shows the deposition rate of the platinum thin film according to the injection time of the platinum precursor. Referring to FIG. 2, when the injection time of the platinum precursor is 5 seconds, it can be seen that the deposition rate is saturated.

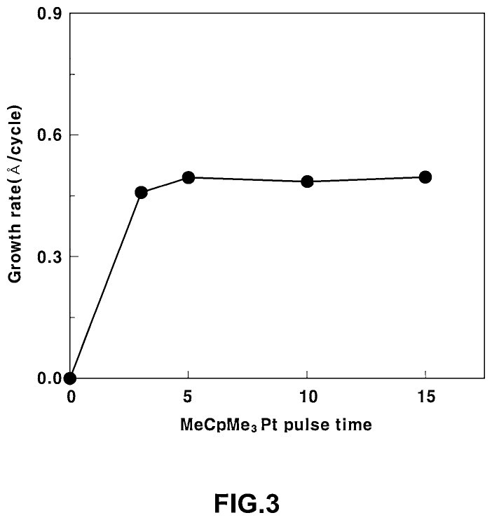

Meanwhile, instead of the platinum precursor, bis(1-dimethylamino-2-methyl-2-butoxide)nickel(II) (Ni(dmamb)₂), which is a nickel (Ni) precursor, was injected using a carrier gas for a predetermined time. Specifically, the temperature of the nickel precursor was about 80° C., and the flow rate of the carrier gas was about 100 sccm. FIG. 3 shows the deposition rate of the nickel thin film according to the injection time of the nickel precursor. Referring to FIG. 3, when the injection time of the nickel precursor is 10 seconds, it can be seen that the deposition rate is saturated.

The above results imply a self-controlled reaction that occurs when synthesizing materials by an atomic layer deposition method and suggest that the atomic layer deposition method using the above precursors is possible successfully.

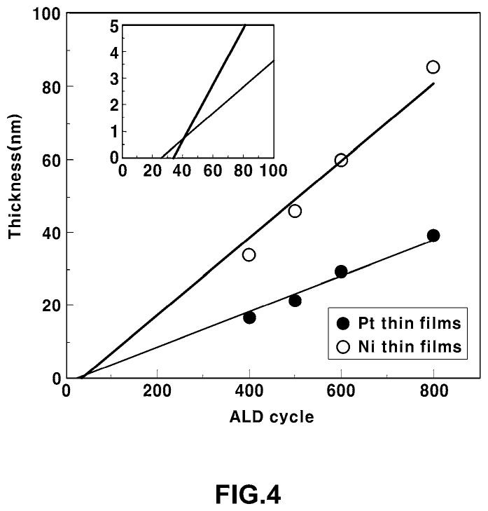

FIG. 4 shows a result of measuring the thickness according to the atomic layer deposition cycle. The graph shown through the extrapolation method increases linearly, which also indicates the self-controlled reaction.

### Examples 1 to 4

Carbon black was introduced into the fluidized-bed reactor, and the internal pressure was adjusted to about 0.6 Torr.

The internal temperature of the fluidized bed reactor was maintained at about 300° C. The temperature of the pipes connected to the fluidized bed reactor was maintained at about 100° C. The temperature inside a container storing the platinum precursor MeCpPtMe₃ was maintained at about 30° C. The internal temperature of a container storing nickel precursor Ni(dmamb)₂ was maintained at about 80° C.

The platinum precursor was injected into the fluidized bed reactor with argon gas, which is a carrier gas. The flow rate of the carrier gas was about 100 sccm, and the injection time was about 120 seconds.

Thereafter, the fluidized bed reactor was purged by injecting argon gas.

Then, oxygen (O₂) as a reaction gas was injected into the fluidized bed reactor at a flow rate of about 30 sccm for about 90 seconds to cause a reaction.

The fluidized bed reactor was purged by injecting argon gas.

This was repeated, as shown in Table 1 below, as the first sub-cycle.

The nickel precursor was injected into the fluidized bed reactor with argon gas, which is a carrier gas. The flow rate of the carrier gas was about 100 sccm, and the injection time was about 240 seconds.

Thereafter, the fluidized bed reactor was purged by injecting argon gas.

Then, hydrogen (H₂) as a reaction gas was injected into the fluidized bed reactor at a flow rate of about 30 sccm for about 90 seconds to cause a reaction.

The fluidized bed reactor was purged by injecting argon gas.

This was repeated, as shown in Table 2 below, as the first sub-cycle.

The super cycle, including the first sub-cycle and the second sub-cycle, was repeatedly performed, as shown in Table 1.

Each resultant product was heat-treated at about 700° C. in a hydrogen atmosphere to obtain alloy catalysts according to Examples 1 to 4.

### Comparative Example

An alloy catalyst was prepared in the same manner as in Example 2, except that heat treatment was not performed.

TABLE 1

| | | | | Whether | |
|---|---|---|---|---|---|
| | | | | heat | Alloy |
| | First | Second | Super | treated | catalyst |
| Division | sub-cycle | sub-cycle | cycle | or not | composition |
| Example 1 | 3 times | 1 time | 4 times | ◯ | Pt 75at % |
| | | | | | Ni 25at % |
| Example 2 | 5 times | 1 time | 2 times | ◯ | Pt 78at % |
| | | | | | Ni 22at % |
| Example 3 | 6 times | 2 times | 2 times | ◯ | Pt 81at % |
| | | | | | Ni 19at % |
| Example 4 | 6 times | 1 time | 2 times | ◯ | Pt 85at % |
| | | | | | Ni 15at % |
| Comparative | 5 times | 1 time | 2 times | X | Pt 78at % |
| Example | | | | | Ni 22at % |

Referring to Table 1, it can be seen that the composition of the alloy catalyst can be appropriately adjusted through the number of the first sub-cycle, the second sub-cycle, and the super cycle.

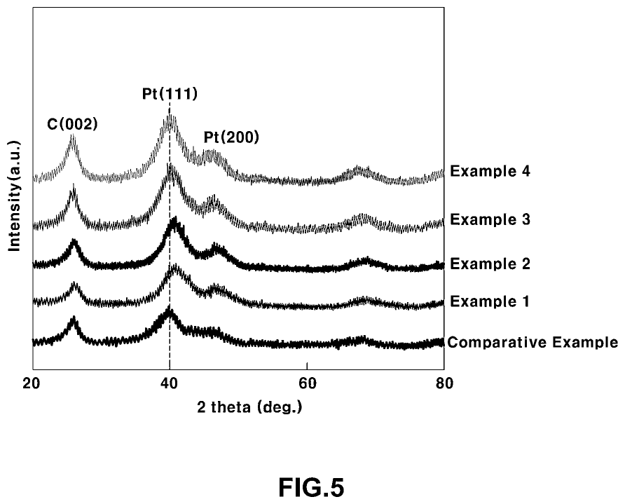

FIG. 5 shows a result of an X-ray diffraction analysis of alloy catalysts according to Examples 1 to 4 and Comparative Examples. Referring to FIG. 5, in Examples 1 to 4, when the diffraction peak of the surface 111 is moved at a high angle as compared to Comparative Example, nickel is introduced into the platinum lattice through heat treatment, and thus alloying is further performed, causing lattice deformation.

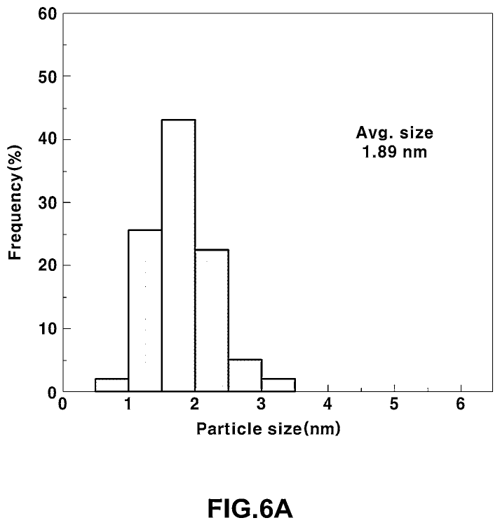

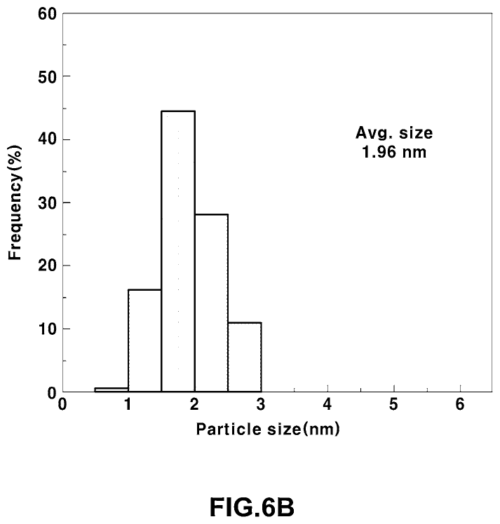

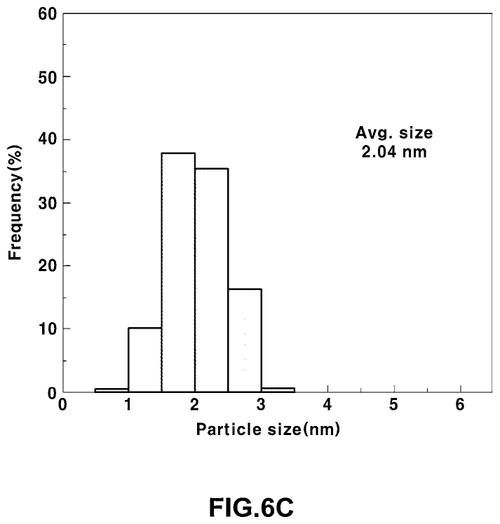

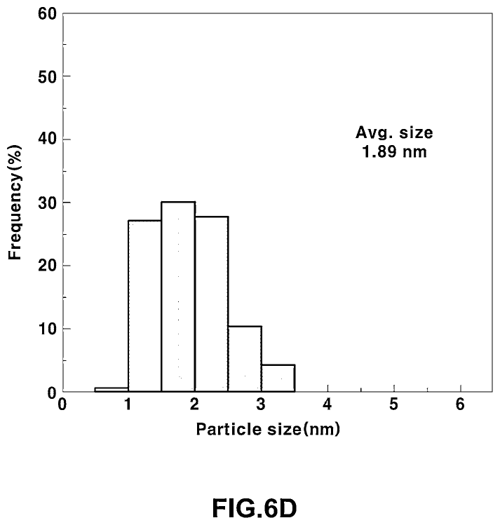

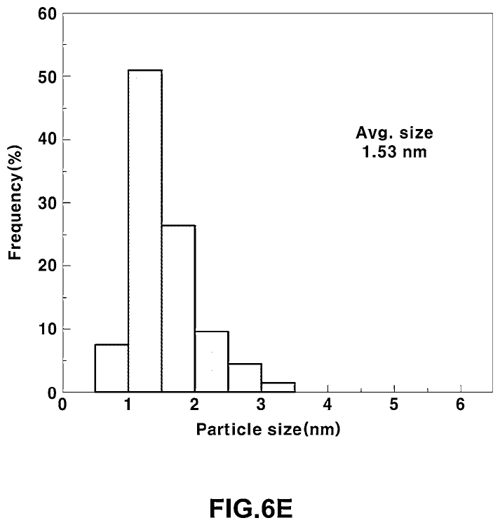

FIG. 6A shows a result of measuring the particle size and distribution of the alloy catalyst according to Example 1. This was plotted by directly checking the particles in the scanning transmission electron microscopy (STEM) image of the alloy catalyst. FIG. 6B shows a result of measuring the particle size and distribution of the alloy catalyst according to Example 2. FIG. 6C shows a result of measuring the particle size and distribution of the alloy catalyst according to Example 3. FIG. 6D shows a result of measuring the particle size and distribution of the alloy catalyst according to Example 4. FIG. 6E shows a result of measuring the particle size and distribution of the alloy catalyst according to the Comparative Example. Referring to FIGS. 6A to 6E, it can be seen that the alloy catalyst of various compositions, according to the present disclosure, has a very uniform particle size and distribution.

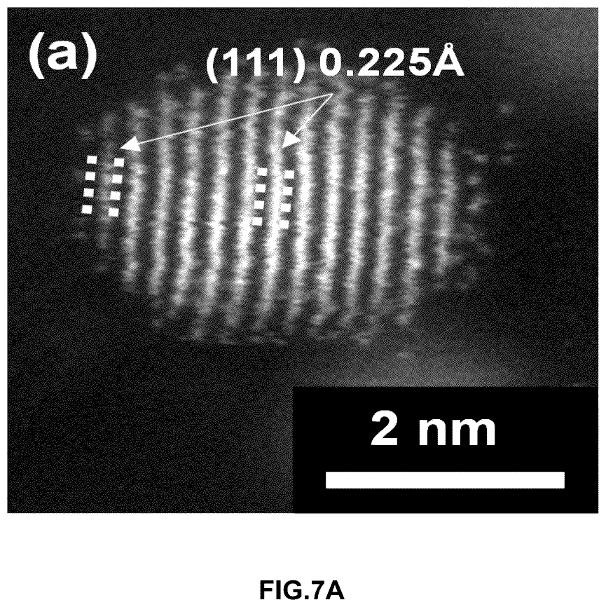

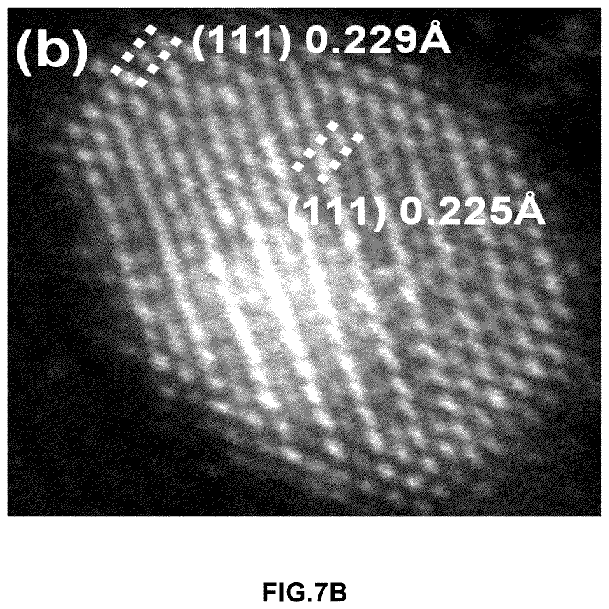

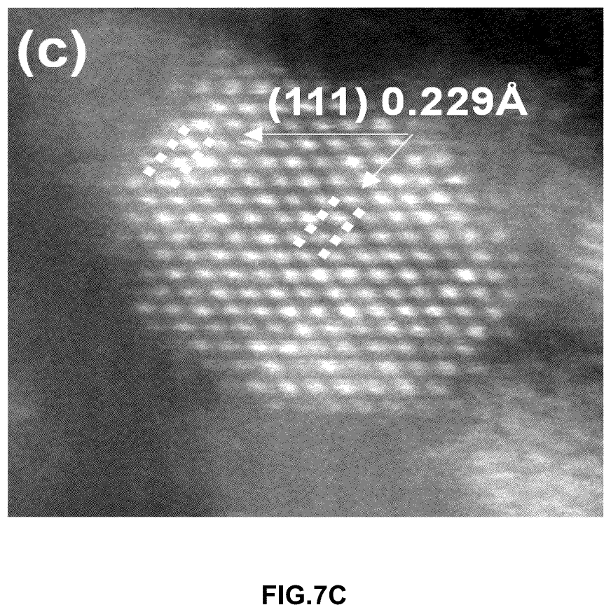

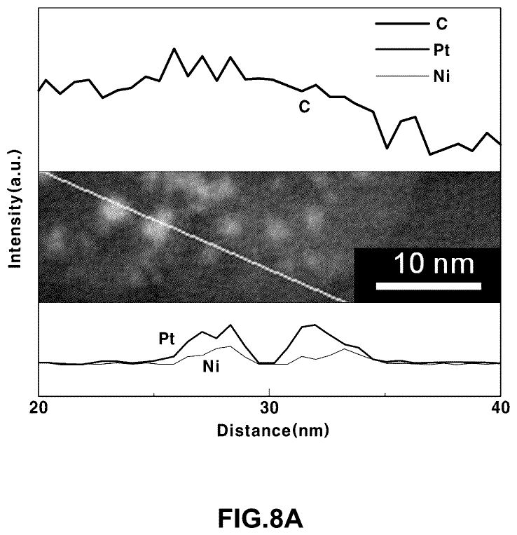

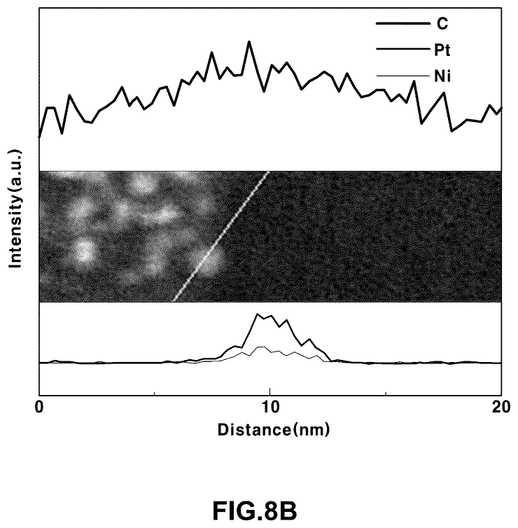

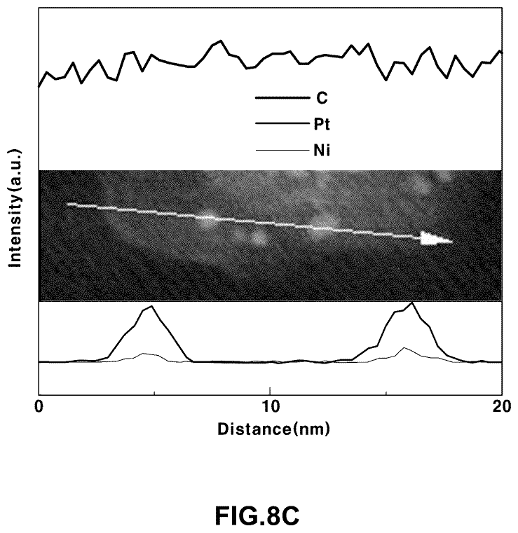

FIG. 7A shows a result of analyzing the alloy catalyst according to Example 1 with a high-resolution transmission electron microscope. FIG. 7B shows a result of analyzing the alloy catalyst according to Example 2 with a high-resolution transmission electron microscope. FIG. 7C shows a result of analyzing the alloy catalyst according to Example 3 with a high-resolution transmission electron microscope. FIG. 8A shows a result of line profiling to determine the composition distribution of one alloy catalyst particle in FIG. 7A. FIG. 8B shows a result of line profiling to determine the composition distribution of one alloy catalyst particle in FIG. 7B. FIG. 8C shows a result of line profiling to determine the composition distribution of one alloy catalyst particle in FIG. 7C.

Referring to FIGS. 7A to 8C, it can be seen that as the platinum composition increases, a platinum layer appears on the particle surface portion of the alloy catalyst after heat treatment and becomes thicker.

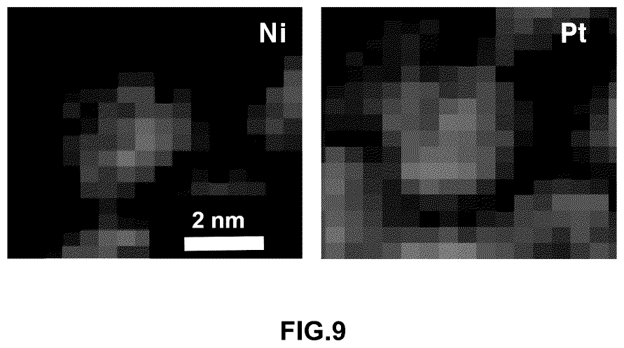

FIG. 9 shows an electron energy loss spectroscopy result for the alloy catalyst according to Example 2. Referring to FIG. 9, it can be seen that the distribution area of platinum in one particle is wider, which means that a platinum layer is formed.

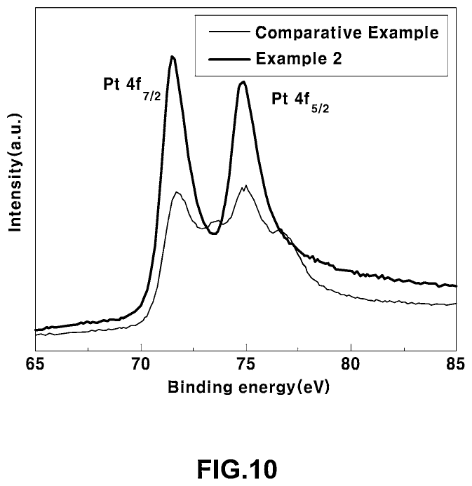

FIG. 10 shows the low-angle X-ray photoelectron spectroscopy (XPS) results of the alloy catalyst according to Example 2 and Comparative Example. It can be seen that in Example 2, in which the heat treatment was performed, the signal related to oxygen disappeared, and the measurement intensity of platinum was increased.

From the above results, it can be confirmed that impurities such as oxygen are eliminated while alloying occurs, and a platinum layer is formed on the surface of the catalyst through additional thermal treatment for the alloy catalyst.

Performances such as the electrochemical activity of the alloy catalysts according to Examples 1 to 4 were evaluated.

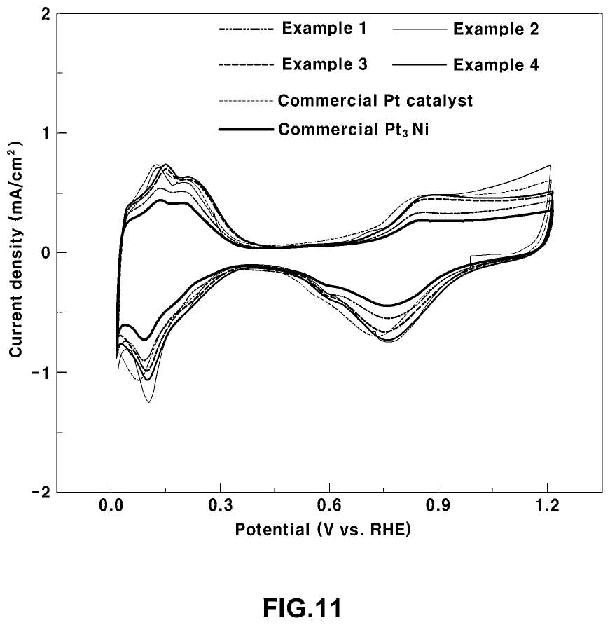

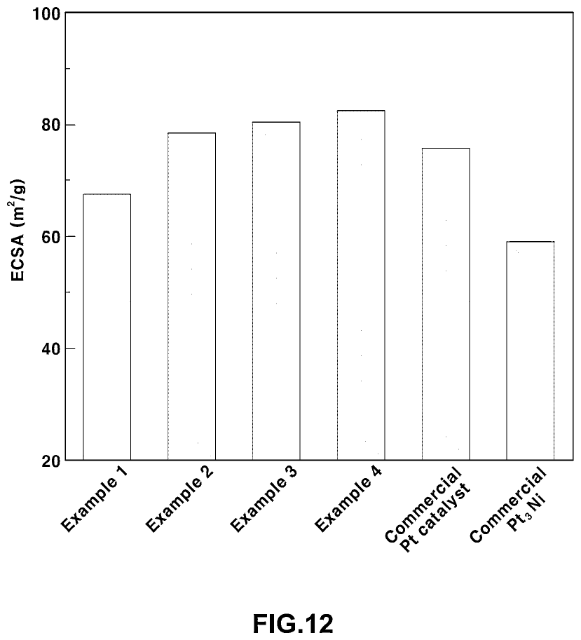

FIG. 11 shows a result of analyzing the alloy catalysts according to Examples 1 to 4 by cyclic voltammetry. For comparison, the results of a platinum catalyst (hereinafter, a commercial platinum catalyst) sold commercially and a platinum nickel alloy catalyst (hereinafter, a commercial alloy catalyst) having the same composition as in Example 2 are also shown. FIG. 12 shows a result of measuring the electrochemically active surface area of each alloy catalyst through the results of FIG. 11. Referring to FIG. 12, the catalytically active surface area of Example 2 remarkably increases compared to Example 1, and the active surface area value increases very slightly as the platinum composition increases. This is considered to be because the platinum layer described above in Example 2 is more clearly formed. On the other hand, all Examples 1 to 4 have a higher electrochemically active surface area compared to the commercial alloy catalyst, which is thought to be due to the relatively denser and well-distributed alloy particles.

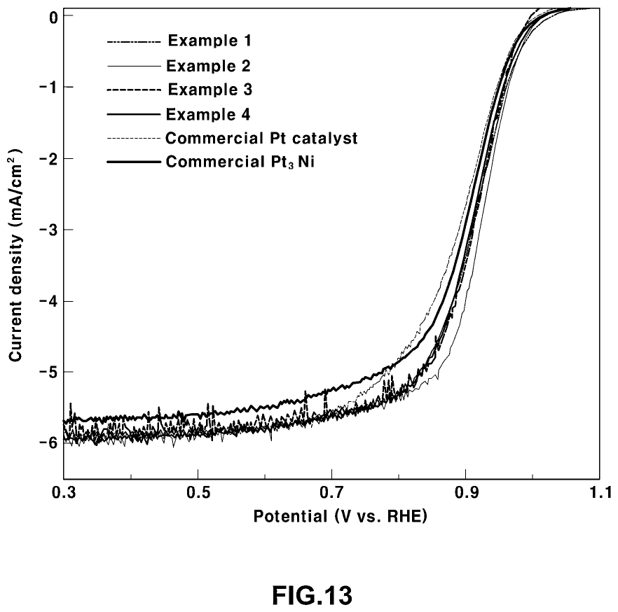

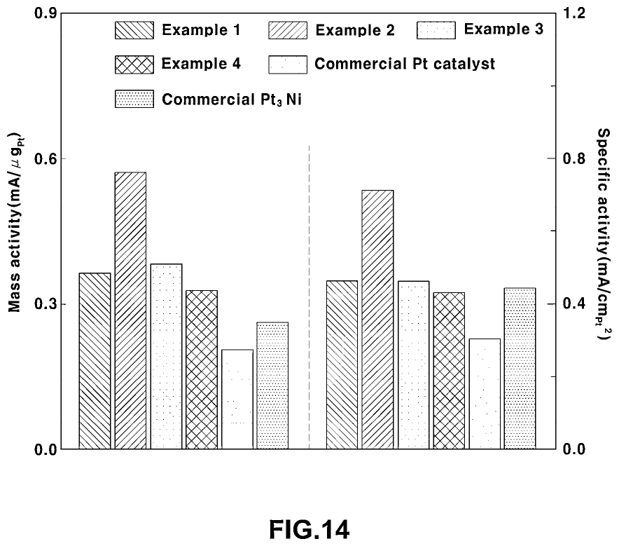

FIG. 13 shows a result of measuring the activity for oxygen reduction reaction by analyzing the alloy catalysts according to Examples 1 to 4 by a linear scanning potential method. FIG. 14 shows a result of calculating the activity per platinum mass and the activity per platinum surface area based on the results of FIG. 13. Example 2 shows the best activity per mass of platinum and activity per platinum surface area. This is considered as a result in that the alloy catalyst composition, according to Example 2, has high catalytic activity due to a change in the electronic structure due to metal-metal interaction and a change in catalytic activity due to lattice constant mismatch, and platinum with very good activity is exposed on the surface.

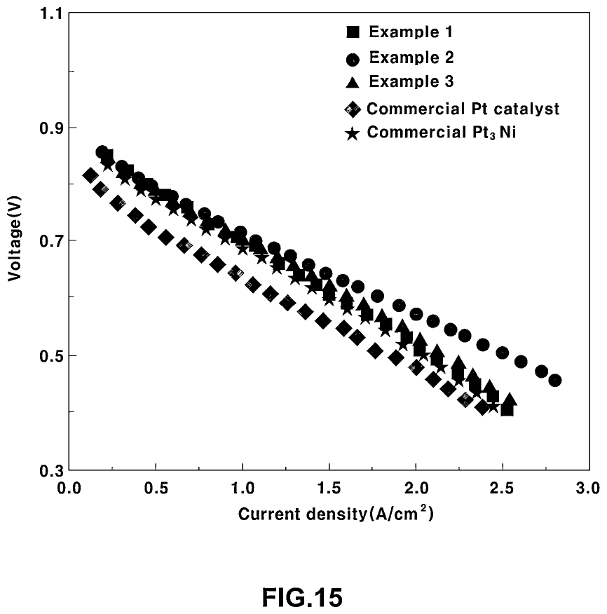

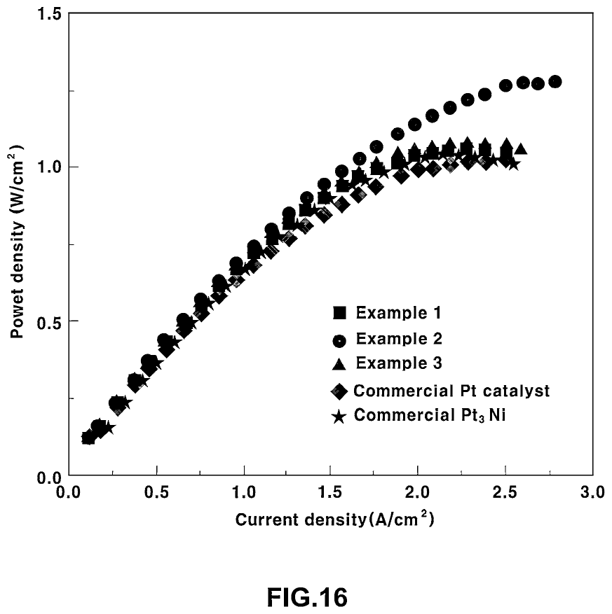

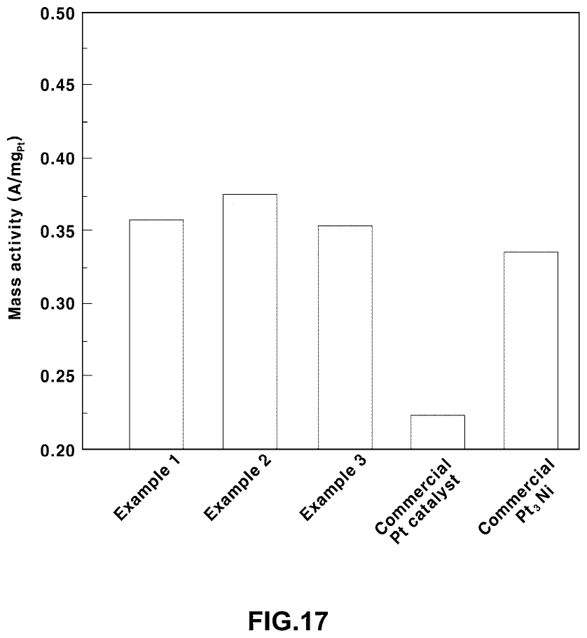

FIG. 15 shows a polarization curve of the fuel cell when the alloy catalyst, according to Examples 1 to 3, is applied to the cathode of the polymer electrolyte exchange membrane fuel cell. FIG. 16 shows a power density curve of the fuel cell when the alloy catalyst, according to Examples 1 to 3, is applied to the cathode of the polymer electrolyte exchange membrane fuel cell. FIG. 17 shows a result of measuring the activity per mass of the alloy catalyst in the fuel cell when the alloy catalyst, according to Examples 1 to 3, is applied to the cathode of the polymer electrolyte exchange membrane fuel cell. Referring to FIGS. 15 to 17, it can be seen that the alloy catalyst, according to Example 2, has the highest current density, the highest maximum power density, and the highest activity per mass under the same voltage standard.

The durability of the alloy catalyst, according to the present disclosure, was evaluated.

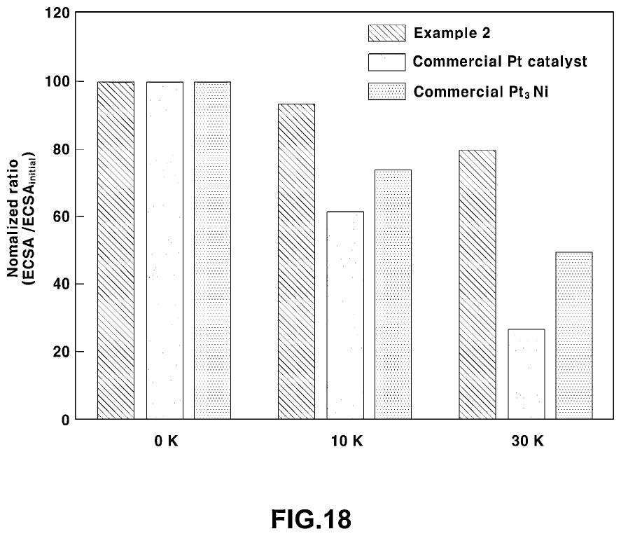

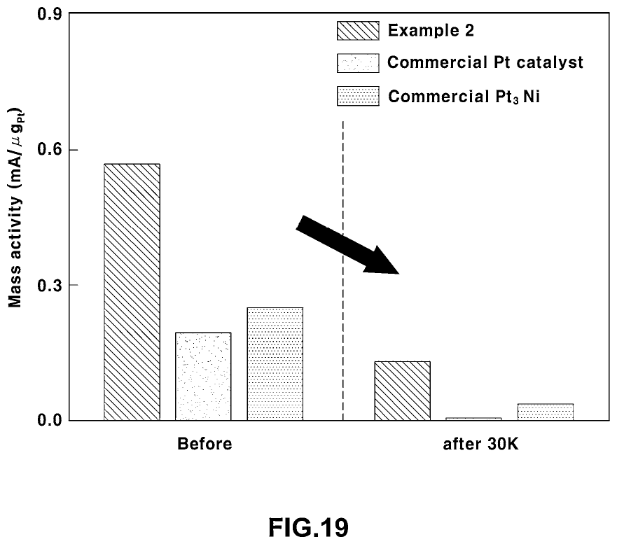

FIG. 18 shows a result of measuring the active surface area of the alloy catalyst when the alloy catalyst, according to Example 2, is applied to the cathode of a polymer electrolyte exchange membrane fuel cell, and the fuel cell is operated for 30,000 cycles using the degraded cyclic voltammetry. FIG. 19 shows a result of measuring the activity per platinum mass of the alloy catalyst when the alloy catalyst, according to Example 2, is applied to the cathode of a polymer electrolyte exchange membrane fuel cell, and the fuel cell is operated for 30,000 cycles by the degradation linear scanning potential method. Compared to a commercial platinum catalyst and a commercial alloy catalyst, the active surface area of the alloy catalyst, according to Example 2 through a degradation test and an activity reduction value per platinum mass, is smaller, and thus it can be seen that the durability is excellent. It is thought that this is because a platinum layer is formed on the surface of the alloy catalyst to prevent the elution of nickel.

As described above in detail, the scope of the present disclosure is not limited to the experimental examples and embodiments, and various modifications and improvements of those skilled in the art defined in the following claims are also included in the scope of the present disclosure.

1. A method for manufacturing an alloy catalyst comprising:
applying a support in a reactor; and
depositing an alloy of platinum and a non-platinum metal on the support through a super cycle comprising a first sub-cycle and a second sub-cycle;
wherein the first sub-cycle comprises:
injecting a platinum precursor into the reactor so that the platinum precursor is adsorbed onto the support;
injecting a first purge gas into the reactor;
depositing platinum on the support by injecting a reaction gas into the reactor; and
injecting a second purge gas into the reactor, and wherein the second sub-cycle comprises:
injecting a non-platinum metal precursor into the reactor so that the non-platinum metal is adsorbed onto the support;
injecting a third purge gas into the reactor;
depositing the non-platinum metal on the support by injecting a reaction gas into the reactor; and
injecting a fourth purge gas into the reactor.

2. The method of claim 1, wherein the reactor comprises a fluidized bed reactor or a rotary reactor.

3. The method of claim 1, wherein the support comprises at least one of a carbon-based support, a metal oxide-based support or any combination thereof.

4. The method of claim 1, wherein the platinum precursor comprises at least one of trimethyl(methylcyclopentadienyl) platinum(IV) (MeCpPtMe₃), platinum(II) bis(acetylacetonate) (Pt(acac)₂), [(1,2,5,6-η)-1,5-hexadiene]dimethyl platinum(II) (HDMP), dimethyl(N,N-dimethyl-3-butene-1-amine-N) platinum (DDAP) or any combination thereof.

5. The method of claim 1, wherein the reaction gas comprises at least one of oxygen (O₂), ozone (O₃), air, hydrogen (H₂), oxygen plasma (O₂ plasma) or any combination thereof.

6. The method of claim 1, wherein the depositing of the platinum on the support is performed by a powder atomic layer deposition method.

7. The method of claim 1, wherein the first purge gas, the second purge gas, the third purge gas and the fourth purge gas each comprises at least one of argon (Ar), helium (He), nitrogen (N₂) or any combination thereof.

8. The method of claim 1, wherein the non-platinum metal comprises at least one of palladium (Pd), gold (Au), silver (Ag), copper (Cu), iron (Fe), cobalt (Co), nickel (Ni), molybdenum (Mo), ruthenium (Ru), rhodium (Rh), tungsten (W), iridium (Ir) or any combination thereof.

9. The method of claim 1, wherein the depositing of the non-platinum metal on the support is performed by a powder atomic layer deposition method.

10. The method of claim 1, wherein the support is maintained in a fluidized state by continuously injecting gas into the reactor while performing the super cycle.

11. The method of claim 1, wherein in the super cycle, the first sub-cycle is performed 2 to 30 times and then the second sub-cycle is performed 1 to 3 times; or
the second sub-cycle is performed 1 to 3 times and then the first sub-cycle is performed 2 to 30 times.

12. The method of claim 1, wherein the super cycle is repeatedly performed 1 to 10 times.

13. The method of claim 1, wherein the super cycle is performed in a temperature of 100° C. to 400° C.

14. The method of claim 1, wherein the method further comprises heat treating a resultant of the super cycle.

15. The method of claim 14, wherein the heat treating is performed in a gas atmosphere comprising at least one of hydrogen (H₂), ammonia (NH₃), nitrogen (N₂), argon (Ar) or any combination thereof.

16. The method of claim 14, wherein the heat treating is performed in a temperature of 400° C. to 1,100° C.

17. The method of claim 1, wherein the alloy catalyst comprises:
75 to 85 at % of the platinum; and
15 to 25 at % of the non-platinum metal.
